(19) United States
(12) Patent Application Publication
(10) Pub. No.: US 2012/0291859 A1
(43) Pub. Date: Nov. 22, 2012

(54) Multi-Junction Semiconductor Photovoltaic Apparatus and Methods

(76) Inventors: Christopher Vineis, Watertown, MA (US); Martin U. Pralle, Wayland, MA (US); James E. Carey, Waltham, MA (US)

(21) Appl. No.: 13/109,767

(22) Filed: May 17, 2011

(51) Int. Cl. H01L 31/06; H01L 31/18

(52) U.S. Cl. 136/255; 438/69; 257/E31.001

(57) ABSTRACT

A photovoltaic device and methods of manufacturing a photovoltaic device are disclosed. A photovoltaic device includes a first photovoltaic cell, a second photovoltaic cell, a semiconductor layer, and a doped layer. The second photovoltaic cell is in electrical communication with the first photovoltaic cell. The semiconductor layer includes a textured portion. The doped layer is configured to create a back surface field, the doped layer disposed between a proximal layer of the second photovoltaic cell and the semiconductor layer.

### TECHNICAL FIELD

The present disclosure relates to the manufacture of photovoltaic devices. More specifically, the present invention is drawn towards thin film photovoltaic devices.

### BACKGROUND

The advantages of thin film solar cells over “thick” cells include reduced material cost, large area and complete module processing, and the ability to be fabricated on flexible and transparent substrates. However, to date, most thin-film technologies have lower efficiencies as compared to thick substrates. The efficiency loss is mainly attributed to absorption losses and crystalline defects. Reduced cost but lower efficiency becomes a hurdle to competing in large-scale power generation applications where there are surface area constraints and installation costs dominate the overall cost structure.

The most common material groups used in thin-film solar cells are silicon (amorphous and polycrystalline), cadmium indium diselenide (CIS and CIGS if gallium is included), and cadmium telluride (CdTe). For exemplary discussion we will discuss the background of thin-film silicon solar cells, but the advantages of laser processing described herein can be extended to other thin-film material systems.

Amorphous silicon and microcrystalline thin films are typically grown/deposited using chemical vapor deposition on a transparent substrate such as glass or a flexible plastic. The semiconductor component of silicon thin film solar cells is typically a few microns in thickness, as compared to hundreds of microns for thick solar cells. The savings in raw material provides an economic advantage and these types of thin film devices save on raw silicon material usage over traditional thick cells because they have much higher absorption efficiency. In addition, the reduction in processing steps and the ability to make entire solar cell modules on one substrate offer significant manufacturing and cost advantages. However, thin-films struggle with a tradeoff of needing enough thickness to absorb sufficient light, and reduced carrier collection efficiency as the semiconductor layers get thicker. Mobilities are often lower in these devices so a strong field and a short travel distance for photocarriers is critical for high efficiency. In addition, growing a thicker film takes more manufacturing time, more material, adds stress, and at some thickness becomes impractical.

The external quantum efficiency (EQE) of a photovoltaic device is the current obtained outside the device per incoming photon. The external quantum efficiency therefore depends on both the absorption of light and the collection of charges. The “external” quantum efficiency of a silicon solar cell includes the effect of optical losses such as transmission and reflection. “Internal” quantum efficiency refers to the efficiency with which photons that are not reflected or transmitted out of the cell can generate collectable carriers. By measuring the reflection and transmission of a device, the external quantum efficiency curve can be corrected to obtain the internal quantum efficiency curve.

$$EQE = \frac{\frac{electrons}{sec}}{\frac{photons}{sec}} = \frac{\frac{current}{charge of 1 electron}}{\frac{total power of photons}{energy of one photon}}$$

In the case of amorphous silicon the band gap is such that light beyond 750 nm is not absorbed (as compared to 1100 nm for thick crystalline silicon). The solar spectrum has more than 50% of its energy in wavelengths longer than 750 nm. Therefore a very large portion of the solar spectrum is not converted to electricity in thin-film amorphous solar cells. A recent approach to improve the performance at longer wavelengths is to add a second solar cell junction beneath the first junction to create a stacked multi-junction solar cell where each junction is tuned to a specific part of the solar spectrum. In this way, light that is not captured by the top cell, transmits through the top cell and is absorbed by the second cell beneath. This of course can be extended to a plurality of cells specifically designed to collect multiple wavebands of solar radiation. The solar cell junction referred to above is the boundary interface where the two regions of the semiconductor device meet and a depletion region is formed. The two regions of the semiconductor device are often formed by doping.

### IV. SUMMARY

Prom the discussion given above it can be appreciated that better photovoltaic devices are desirable. The following discussion provides such improved apparatus and methods of manufacture of the apparatus. Embodiments hereof provide a method of using laser processing to create at least a textured portion (e.g., an absorbing layer) within a multi-junction thin film silicon solar cell that increases the long wavelength light efficiency. More specifically, the embodiments of the present invention include a short pulse laser processing system to create a one or more textured portions (e.g., absorbing layers) in a tandem junction micromorph thin film semiconductor photovoltaic device that has an increase wavelength response. The present invention can have enhanced quantum efficiency at long wavelengths and the high absorption properties can lead to greater than about 15% efficiency in a thin film photovoltaic device.

The combination of high quantum efficiency thin film silicon for short wavelengths and the high quantum efficiency of laser processed silicon for longer wavelengths enables a new type of photovoltaic device that has low material costs and significantly enhanced conversion efficiency. In some cases, the efficiency can be greater than about 5%. In other embodiments the efficiency can be greater than about 10% or even greater than about 15%. In addition, the present photovoltaic device can utilize silicon as a semiconductor material and thereby reduce cost compared to other traditional thin film cell types such as cadmium telluride and copper indium gallium diselenide and does not require the use of toxic materials. Although, this disclosure describes silicon in some embodiments, other materials (e.g., silicon germanium) can be used to achieve similar results.

Through the use of a silicon-type material, combination photovoltaic devices can take advantage of the strengths of current thin-film silicon photovoltaic devices and can enhance the performance at longer wavelengths by using high quantum efficiency laser processed silicon as an absorbing semiconductor layer, i.e. a backstop for light. The wavelengths detectable by the present invention may be in the range of about 400 nm to about 1300 nm.

Embodiments further include a doped layer disposed between the textured silicon layer and a thin film silicon solar cell. The doped layer can create an electrical field or a back surface field that can repel minority carriers (e.g., electrons). Minimizing the number of minority carriers that reach the textured silicon layer can reduce recombination of minority and majority carriers, thereby improving the internal and external efficiency of the thin film silicon solar cell. In some embodiments, the textured silicon layer can be formed by a laser-treatment.

In some embodiments of the present invention, a photovoltaic device includes a substrate layer that includes a conductive substrate layer. The device also includes a first photovoltaic cell disposed on the conductive substrate layer, a conductive layer disposed on the first photovoltaic cell, and a second photovoltaic cell disposed on the conductive layer. The second photovoltaic cell includes a silicon layer having one or more textured portions, which can be laser-treated.

Implementations of the device may include one or more of the following features. At least one photovoltaic cell can be a thin film photovoltaic cell. The first and second photovoltaic cells may be silicon photovoltaic cells. The first photovoltaic cell may be configured to substantially absorb a first wavelength of incident sunlight upon the device, and the second photovoltaic cell may be configured to substantially absorb a second wavelength of incident sunlight upon the device that is longer than the first wavelength. The substrate layer may be flexible. In some implementations, the device can be irradiated with a pulsed laser source to form a textured portion. The irradiating may be performed with femtosecond, picosecond, or nanosecond pulsed laser radiation. The irradiating may further be performed in an inert environment. The device may include a feature wherein the irradiating is performed in an environment that contains a dopant chemical species. The dopant species may include a solid, liquid, or gas. In some implementations, the first photovoltaic cell includes one or more textured portions. The device may further include the feature wherein the second wavelength of incident light can pass substantially unabsorbed through the first photovoltaic cell. In some implementations, the second photovoltaic cell may be a thin film photovoltaic cell with quantum efficiency greater than about 80% for light wavelengths longer than about 900 nanometers. In other implementations, the second photovoltaic cell may be a thin film photovoltaic cell with quantum efficiency greater than about 80% for light wavelengths longer than about 800 nanometers. In yet other implementations, the second photovoltaic cell may be a thin film photovoltaic cell with quantum efficiency greater than about 80% for light wavelengths longer than about 700 nanometers.

The device may include the feature wherein the first photovoltaic cell comprises a P-N junction. In other implementations, the first photovoltaic cell may include a P-i-N junction. The device may also include the feature wherein the second photovoltaic cell comprises a P-N junction. In other implementations, the second photovoltaic cell may include a P-i-N junction.

The device may include the feature wherein the second photovoltaic cell exhibits an absorprance greater than about 80% for light wavelengths longer than about 800 nanometers. In other implementations, the second photovoltaic cell may exhibit an absorptance greater than about 90% for light wavelengths longer than about 800 nanometers. The device may also be laser annealed subsequent to the irradiating of the textured portion.

In general, in another embodiment of the present invention, a photovoltaic device is provided. The photovoltaic device includes a substrate layer, the substrate layer comprising a conductive substrate layer. The device also includes a first p-type layer disposed on the conductive substrate layer, a first i-type layer disposed on the first p-type layer, a first n-type layer disposed on the first i-type layer, a conductive layer disposed on the first n-type layer, a second p-type layer disposed on the conductive layer, a second i-type layer disposed on the second p-type layer, and a second n-type layer disposed on the second i-type layer, wherein the second n-type layer comprises one or more textured portions. In some embodiments, a doped layer can be disposed on the second n-type layer, the doped layer configured to create a back surface field. In some embodiments, the textured portion is laser-treated.

In some embodiments, a photovoltaic device includes a first photovoltaic cell, a second photovoltaic cell, a semiconductor layer, and a doped layer. The second photovoltaic cell is in electrical communication with the first photovoltaic cell. The semiconductor layer includes a textured portion. The doped layer is configured to create a back surface field, the doped layer disposed between a proximal layer of the second photovoltaic cell and the semiconductor layer.

In some embodiments, the doped layer includes a first dopant having a first polarity and the proximal layer of the second photovoltaic cell comprises a second dopant having a second polarity. The first polarity can be the same as the second polarity. In some embodiments, the first polarity and the second polarity are negative. The proximal layer of the second photovoltaic cell can include the semiconductor layer.

A first concentration of the first dopant can be at least about two times, about five times, or about fifty times a second concentration of the second dopant. The first dopant can include a same dopant material as the second dopant. A concentration of the first dopant can be between about 1×10¹⁸/cm³ to about 1×10²⁰/cm³, or about 5×10¹⁸/cm³.

The doped layer can be configured to repel a minority carrier. In some embodiments, the minority carrier includes electrons. An electromagnetic radiation reflecting layer can be disposed between the semiconductor layer and a substrate and/or between the first and second photovoltaic cells.

The first and second photovoltaic cells can include silicon. The first photovoltaic cell can include amorphous silicon. The second photovoltaic cell can include microcrystalline silicon. The first photovoltaic cell can be disposed on a substrate and the second photovoltaic cell can be disposed on the first photovoltaic cell. In some embodiments, the substrate is flexible. A conductive layer can be disposed between the first photovoltaic cell and the substrate and/or between the semiconductor layer and a substrate. The first photovoltaic cell can include a P-N junction or P-i-N junction. The second photovoltaic cell can include a P-N junction or a P-i-N junction.

The textured portion of the semiconductor layer can be formed by a laser-treatment process. In some embodiments, the textured portion of the semiconductor layer can creates a Lambertian distribution of light.

In some embodiments, a photovoltaic device includes a substrate layer, a conductive substrate layer disposed on the substrate layer, a first p-type layer disposed on the conductive substrate layer, a first i-type layer disposed on the first p-type layer, a first n-type layer disposed on the first i-type layer, a first conductive layer disposed on the first n-type layer, a second p-type layer disposed on the first conductive layer, a second i-type layer disposed on the second p-type layer, a second n-type layer disposed on the second i-type layer, a doped layer disposed on the second n-type layer, and a semiconductor layer disposed on the doped layer. The doped layer is configured to create a back surface field. The semiconductor layer includes a textured portion.

An electromagnetic radiation reflecting layer can be disposed on the second conductive layer. The textured portion of the semiconductor layer can be formed by a laser-treatment process. The doped layer can include a first dopant material having a first polarity. The semiconductor layer can include a second dopant material having a second polarity. The first and second dopant polarities can be the same. In some embodiments, the first and second dopant polarities are negative.

In some embodiments, a method of manufacturing includes depositing a first photovoltaic cell on a substrate, depositing a second photovoltaic cell on the first photovoltaic cell, depositing a doped layer configured to create back surface field on the second photovoltaic cell, depositing a semiconductor layer on the doped layer, and forming a textured portion of the semiconductor layer. The back surface field layer has a dopant concentration greater than a dopant concentration of a proximal layer of the second photovoltaic cell.

The method can include depositing an electromagnetic radiation reflecting layer on the semiconductor layer. The textured portion can be formed by irradiating at least a portion of the semiconductor layer with a pulsed laser source.

The technique used to make this type of single-material, combination photovoltaic device can also be extended to multi-material, combination photovoltaic devices for further performance benefits.

Specific examples of applications of the present methods and apparatus include thin-film photovoltaic power generation.

Other uses for the methods and apparatus given herein can be developed by those skilled in the art upon comprehending the present disclosure.

### IV. BRIEF DESCRIPTION Of DRAWINGS

For a fuller understanding of the nature and advantages of the present invention, reference is being made to the following detailed description of embodiments and in connection with the accompanying drawings, in which:

FIG. 1 illustrates a cross section of an exemplary multi-junction thin-film solar cell architecture according to some embodiments hereof;

FIG. 2 illustrates an exemplary system for manufacturing an exemplary multi-junction thin film solar cell including a textured silicon layer according to some embodiments of the present invention;

FIG. 3 illustrates a flow chart of various stages of an exemplary method of making a multi-junction thin film photovoltaic device according to embodiments of the present invention

FIG. 4 presents exemplary quantum efficiency data plots of four different types of solar cells.

FIG. 5 illustrates a cross section of an exemplary multi-junction thin-film solar cell architecture according to some embodiments hereof.

FIG. 6 illustrates a flow chart of various stages of an exemplary method of making a multi-junction thin film photovoltaic device according to embodiments of the present invention

### V. DETAILED DESCRIPTION

As disclosed above, the present invention describes systems and articles of manufacture for providing multi-junction thin-film semiconductor photovoltaic devices and methods for making and using the same. In some embodiments, the multi-junction thin-film semiconductor device can include at least one textured portion to enhance absorption characteristics of the device. The textured portion can include a conical structure or microstructure morphology. For example, the textured portion can include a Lambertian structure having micron-sized height variations. In some embodiments, the textured portion can be formed by laser-processing or by other known techniques.

In some embodiments, at least a portion comprising a semiconductor material, for example silicon, is irradiated by a short pulse laser to create modified micro-structured surface morphology that includes a textured portion. The laser processing can be the same or similar to that described in. U.S. Pat. No. 7,057,256, which is hereby incorporated herein by reference. The textured semiconductor portion can be made to have advantageous light-absorbing properties. In some cases this type of material has been called “black silicon” due to its visually darkened appearance after the laser processing and because of its enhanced absorption of visible and infrared radiation compared to other forms of silicon.

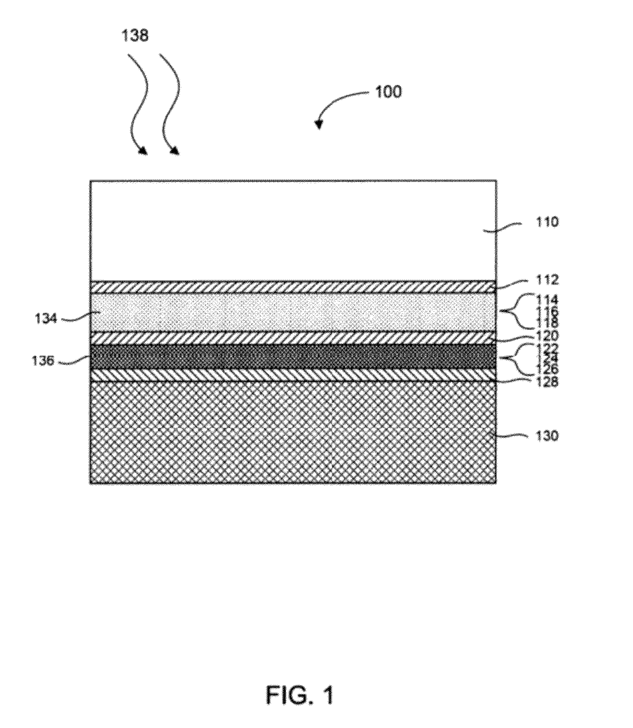

We now turn to a description of an exemplary multi-junction thin film photovoltaic device as shown in FIG. 1. More specifically, FIG. 1 illustrates a cross-section of an exemplary embodiment of a photovoltaic device having a plurality of junctions and a textured portion. For purposes of this embodiment, the semiconductor material can be silicon. One skilled in the art will appreciate that other semiconductor materials may be used to achieve similar results. The photovoltaic device 100 may include a substrate layer 110, a conductive substrate layer 112, a p-type thin film silicon layer 114, an i-type or intrinsic thin film silicon layer 116, an n-type thin film silicon layer 118, a conductive interlayer 120, a p-type thin film silicon layer 122, an i-type thin film silicon layer 124, a n-type thin film silicon layer 126 having at least one textured portion, a conductive electrical contact layer 128, and an encapsulant layer 130.

The substrate layer 110 may be comprised of a suitable material such as a polymer or glass. Depending on the material the substrate may have flexible and/or structural characteristics. Other materials, known to those skilled in the art, that are at least partially transparent to light having wavelengths greater than about 300 nm may be used. The structural substrate layer 110 provides a base for the conductive substrate layer 112. The conductive substrate layer 112 may be of any suitable material such as aluminum or a transparent conductive oxide layer. The p-type thin film silicon layer 114 can be in contact with the substrate layer 110. The p-type thin film silicon layer 114 is an appropriate thickness for the application, such as about 1 nm to about 5,000 nm thick, about 1 nm to about 1,000 nm, about 1,000 nm to about 2,000 nm, about 2,000 nm to about 3,000 nm, about 3,000 nm to about 4,000 nm, about 4,000 nm to about 5,000 nm, about 5 nm to about 100 nm, or ranges therebetween. An intrinsic or i-type thin film silicon layer 116 of appropriate thickness, e.g., about 0 nm to about 5,000 nm thick, about 1 nm to about 1,000 nm, about 1,000 nm to about 2,000 nm, about 2,000 nm to about 3,000 nm, about 3,000 nm to about 4,000 nm, about 4,000 nm to about 5,000 nm, about 500 nm to about 1000 nm, or ranges therebetween, can be disposed on top of the p-type silicon layer 114. In some embodiments, an i-type silicon layer may not be present. The top surface of the i-type thin film silicon layer 116 can be in contact with the n-type thin film silicon layer 118. In some embodiments, non thin film layers can be used. The n-type textured silicon layer 118 may be of an appropriate thickness for a specific application, for example, between about 10 to about 5000 nm thick, about 1 nm to about 1,000 nm, about 1,000 nm to about 2,000 nm, about 2,000 nm to about 3,000 nm, about 3,000 nm to about 4,000 nm, about 4,000 nm to about 5,000 nm, about 500 nm to about 1000 nm, about 100 nm to about 500 nm, or ranges therebetween. The n-type textured silicon layer 118 can be formed by laser processing, as described in U.S. Pat. No. 7,057,256, which is incorporated by reference. For example, the n-type silicon layer 118 have a textured portion can have a conical structure or microstructure morphology. For example, the textured portion can include a Lambertian structure having micron-sized height variations.

Suitable processes for forming at least one textured portion on the n-type textured silicon layer 118 can include laser irradiation, photolithography, plasma etching, reactive ion etching, porous silicon etching, lasing, chemical etching (e.g. anisotropic etching, isotropic etching), nanoimprinting, material deposition, selective epitaxial growth, and the like, including combinations thereof.

The three layers, p-type 114, i-type 116, n-type 118, may comprise a first single photovoltaic cell 134 having extended wavelength properties. The first single photovoltaic cell 134 includes amorphous silicon. Other suitable materials for the first single photovoltaic cell 134 include amorphous SiGe, microcrystalline Si, microcrystalline SiGe, or combinations thereof, including combinations with amorphous silicon. A conductive layer 120 may be disposed between the first photovoltaic cell 134 and a second photovoltaic solar cell 136. The conductive layer 120 may be of any suitable material such as zinc oxide or a transparent conductive oxide layer. The conductive layer 120 can be between about 5 nm to about 5,000 nm thick, about 1 nm to about 1,000 nm, about 1,000 nm to about 2,000 nm, about 2,000 nm to about 3,000 nm, about 3,000 nm to about 4,000 nm, about 4,000 nm to about 5,000 nm, about 500 nm to about 1,000 nm, about 100 nm to about 500 nm, 5 nm to 500 nm, or ranges therebetween. The conductive layer 120 can reflect a portion of light (e.g., wavelengths less than about 750 nm) that was not initially absorbed by the first photovoltaic cell 134, thereby increasing the efficiency of the device 100.

The second photovoltaic cell 136 may comprise the p-type layer 122, i-type layer 124, and n-type layer 126. The second photovoltaic cell 136 includes microcrystalline silicon. Other suitable materials for the second single photovoltaic cell 136 include amorphous SiGe, amorphous Si, microcrystalline SiGe, or combinations thereof, including combinations with microcrystalline silicon. The p-type thin film silicon layer 122 can be in contact with conductive layer 120 and i-type thin film silicon layer 124. The p-type thin film silicon layer 122 is an appropriate thickness for the application, such as about 1 nm to about 5,000 nm thick, about 1 nm to about 1,000 nm, about 1,000 nm to about 2,000 nm, about 2,000 nm to about 3,000 nm, about 3,000 nm to about 4,000 nm, about 4,000 nm to about 5,000 nm, about 500 nm to about 1,000 nm, about 100 nm to about 500 nm, 5 nm to 500 nm, or ranges therebetween. An intrinsic or i-type thin film silicon layer 124 of appropriate thickness, e.g., about 0 nm to about 5000 nm thick, about 1 nm to about 1,000 nm, about 1,000 nm to about 2,000 nm, about 2,000 nm to about 3,000 nm, about 3,000 nm to about 4,000 nm, about 4,000 nm to about 5,000 nm, about 500 nm to about 1,000 nm, about 100 nm to about 500 nm, or ranges therebetween, may be disposed between and may be in contact with the p-type thin film silicon layer 122 and an n-type silicon layer 126 having a textured portion. In some embodiments, the n-type textured silicon layer 126 can be textured and/or laser processed, e.g., such as by the laser processing method described in U.S. Pat. No. 7,057,256, which is incorporated by reference. Suitable processes for forming at least one textured portion on the n-type textured silicon layer 126 can include laser irradiation, photolithography, plasma etching, reactive ion etching, porous silicon etching, lasing, chemical etching (e.g. anisotropic etching, isotropic etching), nanoimprinting, material deposition, selective epitaxial growth, and the like, including combinations thereof.

In some embodiments, an i-type silicon layer (e.g., the i-type layer 124) may not be present. The top surface of the i-type thin film silicon layer 124 may be in direct contact with the p-type thin film silicon layer 126. As previously mentioned, the n-type thin film silicon layer 126 may be in contact with the i-type silicon layer 124 and a conductive layer 128, and may be of an appropriate thickness for a specific application, for example, between about 10 nm to about 5,000 nm thick, about 1 nm to about 1,000 nm, about 1,000 nm to about 2,000 nm, about 2,000 nm to about 3,000 nm, about 3,000 nm to about 4,000 nm, about 4,000 nm to about 5,000 nm, about 500 nm to about 1,000 nm, about 100 nm to about 500 nm, 5 nm to 500 nm, or ranges therebetween. In addition, the n-type silicon layer 126 may be a laser processed layer and/or include a textured portion, which can enhance the absorption properties of the layer and ultimately the overall absorption properties of the device 100. An encapsulant layer 130 can be comprised of a material that is at least partially transparent to wavelengths from about 300 nm to about 1300 nm and may be in contact with conductive layer 128. Incidentally, the conductive layer 128 can be comprised of any electrically and/or thermally conductive material, e.g., a metal, an alloy or conductive transparent oxide materials, or combinations thereof. Referring to FIG. 1, incident sunlight 138 may strike and pass through either the substrate layer 110 or the encapsulant layer 130 of the photovoltaic device 100 whereby at least portions of various wavelengths of the sunlight pass through the device can be absorbed by the layers 114, 116, 118, 122, 124, and 126 of the photovoltaic device 100.

The incident sunlight 138 includes relatively shorter wavelengths of light which are absorbed and converted into photocarriers within the p-type thin film silicon layer 114, i -type thin film silicon layer 116 and n-type thin film silicon layer 118. Longer wavelengths of incident sunlight 138 can pass unabsorbed through the first photovoltaic cell 134, such that the longer wavelengths of light may be absorbed in the second photovoltaic cell 136, in silicon n-type layer 126 (which can include a textured and/or a laser-processed portion), the i-type layer 124, and the p-type layer 122. Thus, the silicon layer 126 (which can be a textured and/or a laser-processed portion) may perform as a back-stop for longer wavelength light. In addition to absorption, high energy conversion can require that photocarriers are created and collected efficiency.

Electrical contacts (not shown) or ohmic contacts may be included in the present invention to aid in the transfer of electrical energy. The electrical contacts may comprise any metal or alloy that enables the flow of electricity.

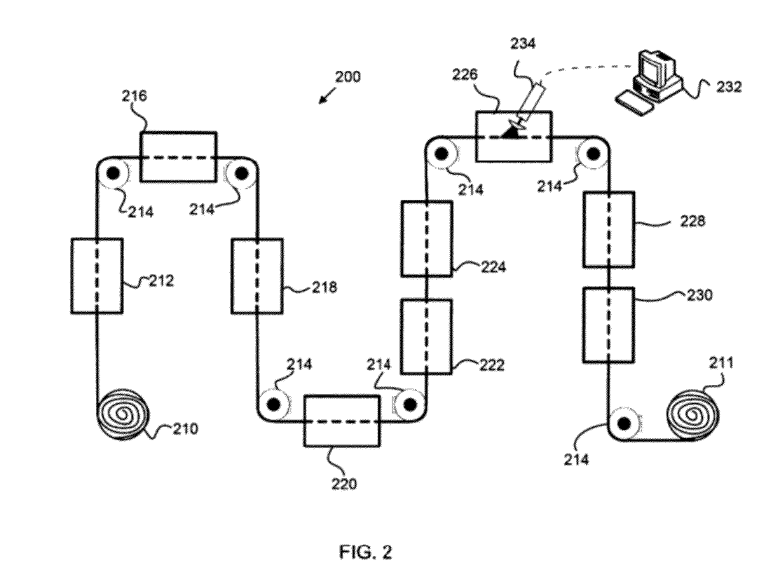

FIG. 2 illustrates an exemplary method and apparatus 200 for forming at least one textured portion in a thin film silicon multi-junction solar cell. One skilled in the art will recognize that other methods can be employed to form the textured portion, as described herein. The laser processing method and apparatus 200 may include appropriate equipment and processes to utilize a conveyor belt or a roll-to-roll process for laser processing the silicon for thin film solar cells (e.g., to produce textured silicon). Thus, a thin layer of silicon may be deposited on a flexible substrate and wound onto a roll for further processing. The substrate may be configured with a conductive material. The thin film layer of silicon deposited onto a conductive substrate can be provided in an automated process such as roll-to-roll to be laser processed with femtosecond laser pulses in a gas environment that contains a desired dopant chemical species (such as but not limited to nitrogen, phosphorous, sulfur, etc.). This laser processing can be accomplished by rastering a laser across the silicon surface or by using multiple laser beams. In some embodiments, laser processing of the silicon layer is performed with a curtain of laser light using one or more cylindrical lenses so that entire lines of silicon are laser processed as they pass beneath the laser light in a roll to roll or conveyor belt process.

The laser processing is comprised of illuminating the desired silicon layer with a plurality of short laser pulses so as to uniformly improve the long wavelength quantum efficiency of the laser processed layer. In some embodiments, the laser pulses are at high enough energy to be above the melting threshold of the irradiated semiconductor. The number of laser pulses can vary from 1 per area to many hundreds per area so as to sufficiently alter the semiconductor surface (e.g., to create a textured portion of the semiconductor surface) to ensure increased quantum efficiency as compared to amorphous silicon at wavelengths longer than about 750 nm. The ambient environment during laser irradiation can include a desired dopant gas, liquid or solid or an inert environment. In some embodiments, an inert environment can be employed where the dopant species of the laser processed layer is included by chemical vapor deposition.

In some embodiments, a substrate comprised of a glass supporting substrate, a thin transparent conductive layer, a layer of thin p-doped hydrogen passivated amorphous silicon (aSi:H), a layer of intrinsic amorphous silicon (aSi:H), a layer of n-doped silicon (aSi:H), a thin transparent conductive layer, a layer of thin p-doped microcrystalline silicon, and a layer of i-doped microcrystalline silicon is prepared for laser processing. The intrinsic microcrystalline silicon layer is then irradiated with between about 1, about 10, about 20, about 30, about 40, about 50, or ranges therebetween, laser pulses of duration in between about 20 fs and about 750 fs, about 100 fs, about 200 fs, about 300 fs, about 400 fs, about 500 fs, about 600 fs, about 700 fs, or ranges therebetween, and at a fluence between 1 kJ/m2 and 6 kJ/m2, about 2 kJ/m2, about 3 kJ/m2, about 4 kJ/m2, about 5 kJ/m2, about 6 kJ/m2, or ranges therebetween, and can produce a textured portion in some embodiments. The laser irradiation can be carried out in an ambient environment that contains a n-type dopant species (such as phosphorous, sulfur, etc.). However, it can be understood by those skilled in the art that the laser process can also be performed to introduce a p-type dopant into a structure that is comprised of an n-type layer covered by an intrinsic silicon layer. In addition, the dopant species in the laser processed layer can be introduced into the semiconductor substrate prior to laser irradiation.

Subsequent to forming at least one textured portion, which in some embodiments can include laser processing the silicon layer, an anneal process is carried out to activate the dopant species implanted during texture formation step. This may be carried out through any means of annealing (e.g., rapid thermal annealing, laser annealing, furnace annealing, etc.). At this point the laser processed (e.g., textured) silicon is a doped n-type or p-type layer depending on the dopant species used during laser processing.

Manufacturing thin film multi-junction photovoltaic cells with laser processed portions can be commercially feasible, and can conform to existing methods of manufacturing thin film flexible solar cells. The problem, however, is that the multi-junction device with an amorphous silicon layer (e.g., photovoltaic cell 134) cannot be traditionally annealed without at least partially damaging the amorphous layer. Thus the current method discloses laser annealing subsequent to the laser processing which will not thermally affect the amorphous layer.

Referring to FIG. 2, with further reference to FIG. 1, various stages of a process 200 are shown for manufacturing a multi-junction thin film solar cell including a silicon layer having a textured portion. The multi-junction photovoltaic device 100 in FIG. 1 is manufactured upside down such that the top transparent substrate layer 110 and conductive substrate layer 112 are provided in the process 200 on a flexible roll 210. During the manufacturing process 200, the top substrate layers of the photovoltaic device 100 become the bottom base layer from which the rest of the device 100 is built upon. The process 200 includes providing the flexible substrate layers 110, 112, from the substrate roll 210 to the p-doped silicon layer deposition process step 212, where an appropriate thickness of p-doped silicon 114 is disposed on the conductive substrate layer 112. The process 200 also includes a plurality of roller elements 214 to facilitate the transport of the flexible substrate through the process 200. The process 200 further includes depositing of an intrinsic layer of silicon (step 216), where a layer of silicon 116 of appropriate thickness is disposed on top of the p-type layer 114. The n-doped silicon layer deposition step 218 disposes an n-type thin film silicon layer 118 layer of appropriate thickness onto the first i-type layer 116. Next, the conductive interlayer step 220 disposes a transparent conducting layer 120 on top of the first n-type thin film silicon layer 118. The second p-doped silicon layer deposition process step 222 places the second p-type layer 122, of appropriate thickness, on top of the conductive interlayer 120. The second deposition of an intrinsic layer of silicon step 224 places the second i-type layer 124 on top of the second p-type layer 122. A textured portion of the surface is formed on the silicon in step 226. The process can include directing an appropriately sized laser beam or curtain of laser light onto the silicon in an automated manner as the silicon layer passes through an appropriate environment to introduce n-type dopant during laser irradiation. The laser processing can be accomplished by the laser assembly 234 via rostering the laser across the silicon surface or by using multiple laser beams. The laser assembly 234 may be operatively coupled to a control computer 232 which may control such variables as frequency, duration, fluence, and targeting of the laser assembly 234 as well as other system variables such as the linear speed of the flexible substrate supply and take-up rolls 210, 211. An automated process may be considered a process which can be properly set up by a user to utilize control equipment such as a computer to control systems, machinery, and processes, thereby reducing the need for human intervention. Although laser processing is described herein, one skilled in the art will recognize that other processing techniques can be used to form the textured portion of the surface or similar surfaces.

In some embodiments, laser processing of the silicon layer is performed with a curtain of laser light using one or more cylindrical lenses so that substantially all of the width of the web of flexible silicon is laser processed as it passes beneath the laser light in a roll to roll or conveyor belt process. In some embodiments, one laser beam may be focused to cover the width of the silicon layer and in other embodiments, multiple laser beams may be focused to cover the width of the silicon layer.

Subsequent to the laser processing step 226, the process 200 includes laser annealing 228 the processed silicon to activate the dopant species implanted during laser processing 226 without damaging the previously deposited amorphous photovoltaic cell 134. The final conducting layer deposition step 230 may be configured to deposit a conductive electrical contact layer 128 on top of the laser processed n-type thin film silicon layer 126. Although not shown, an encapsulant layer deposition step may be included before the take up roll 211.

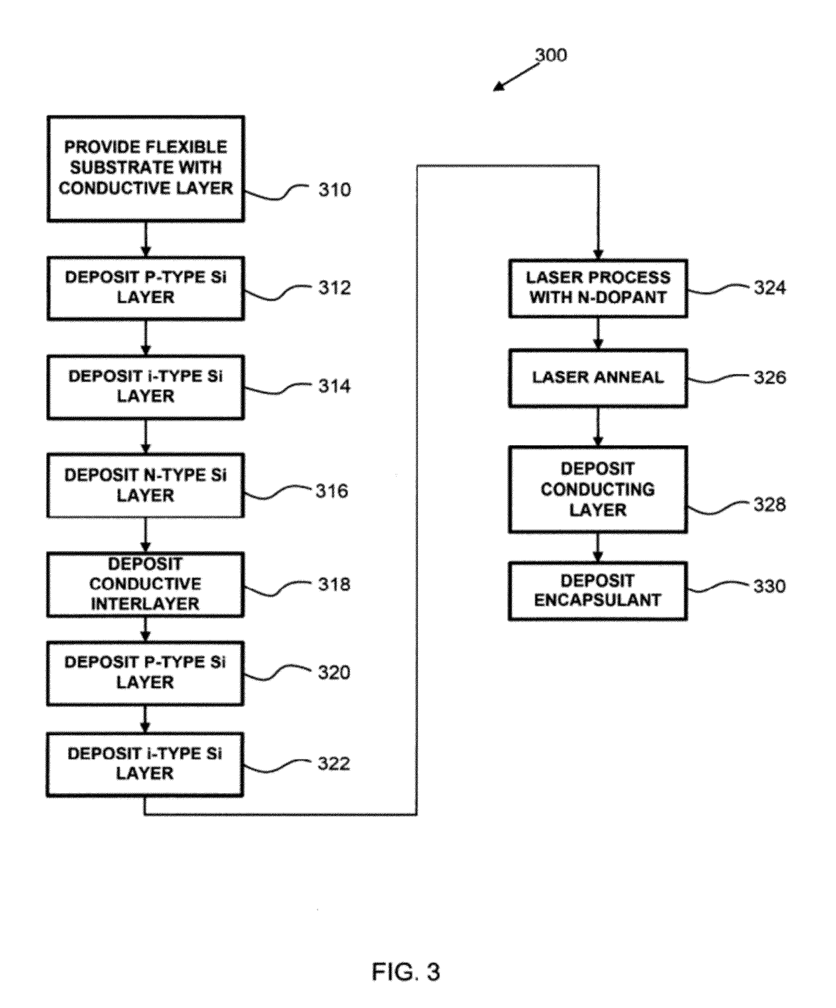

Referring to FIG. 3, with further reference to FIGS. 1 and 2, various stages of a process 300 are shown for manufacturing a multi-junction thin film solar cell including a laser processed silicon layer. The process 300 includes providing a thin film layer of silicon deposited onto a substrate including an appropriate transparent conductive layer 310, depositing a thin layer of amorphous silicon 312 onto the conductive layer so that there is a layer of p-doped silicon on top of the conductive layer, depositing an intrinsic layer 314 on top of the p-doped silicon layer, and depositing a thin layer of n-doped amorphous silicon 316 on top of the first intrinsic layer to form an amorphous silicon photovoltaic cell 134 with a P-i-N junction. The process 300 also includes depositing a conductive interlayer 318 on top of the n-doped amorphous silicon layer, depositing a layer of thin p-doped microcrystalline silicon 320 on top of the transparent conductive interlayer, depositing a layer of i-doped microcrystalline silicon 322 on top of the p-doped microcrystalline silicon layer, and laser processing the intrinsic microcrystalline silicon layer 324 in an ambient environment that contains an n-type dopant species to form a n-doped silicon layer. In some embodiments, the intrinsic layer can be omitted, thereby yielding a P-N junction. The process 300 includes subsequently laser annealing 326 to activate the dopant species implanted during laser processing while avoiding causing thermal damage to the amorphous silicon photovoltaic cell 134. In some embodiments, a n-type layer is deposited on the i-doped microcrystalline silicon 322 and a doped layer is deposited on the n-type layer. A second n-doped microcrystalline layer can be deposited on the n-type layer and textures can be formed in the second n-doped microcrystalline (e.g., by the laser anneal 326 process).

The process 300 also includes depositing a conducting back contact layer 328 on top of the laser processed microcrystalline silicon layer, and depositing an encapsulant layer 330 on top of the back electrical contact layer.

As stated and described herein, the thin film systems and the method of manufacturing thereof can produce a thin film system with greater quantum efficiencies. In particular, quantum efficiency measures the efficiency of light power that is converted to electric power. The invention described herein can achieve one or more of the following quantum efficiencies: quantum efficiencies greater than about 85% for wavelengths between about 700 nm and about 1050 nm; quantum efficiencies greater than about 85% in one wavelength between about 900 nm and about 1100 nm; quantum efficiencies greater than about 90% in one wavelength beyond about 700 nm for a thin film; quantum efficiencies greater than about 80% in one wavelength beyond about 900 nm for a thin film of silicon.

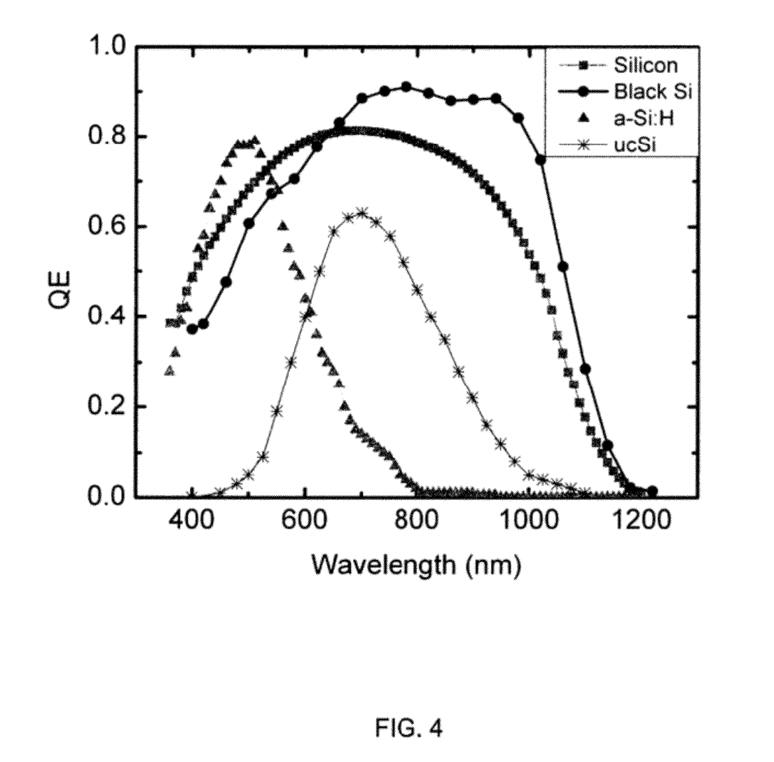

FIG. 4 shows exemplary quantum efficiency curves for four photovoltaic devices. A typical amorphous silicon solar cell, a typical high efficiency monocrystalline solar cell, a typical microcrystalline cell (μcSi), and a short pulse laser processed silicon solar cell (Black Si) as disclosed herein. The laser processed solar cell can have significantly increased quantum efficiency as compared to the amorphous silicon and microcrystalline solar cells for wavelengths longer than 700 nm and can have increased quantum efficiency as compared to a high efficiency monocrystalline solar cell or a microcrystalline solar cell for wavelengths longer than 800 nm.

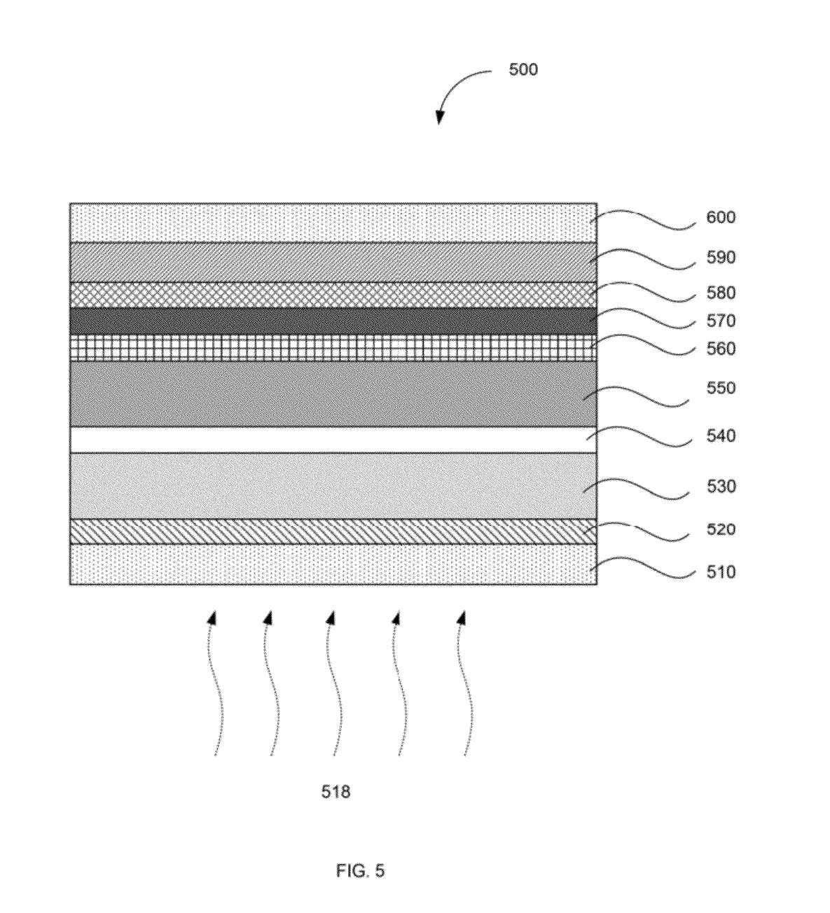

FIG. 5 illustrates a cross section of an exemplary multi-junction thin-film solar cell architecture according to some embodiments. The photovoltaic device 500 includes a substrate layer 510, a conductive substrate layer 520, a first photovoltaic cell 530, an optional conductive substrate layer 540, a second photovoltaic cell 550, a doped layer 560, a textured layer 570 (i.e., a layer having one or more textured portions), a conductive substrate layer 580, an optional reflector layer 590, and a substrate layer 600.

The substrate layer 510 can be same as substrate layer 110 described above. The conductive substrate layer 520 is disposed on the substrate layer 510. The conductive substrate layer 520 can be the same as the conductive substrate layer 112 described above. The first photovoltaic cell 530 is disposed on and in electrical communication with the conductive substrate layer 520. In some embodiments, the first photovoltaic cell 530 can include amorphous silicon, amorphous SiGe, microcrystalline Si, microcrystalline SiGe, or combinations thereof. The first photovoltaic cell 530 can include a first p-type layer, a first i-type layer, and a first n-type layer (e.g., a P-i-N junction). The first p-type layer can be disposed on the conductive substrate layer 520. The first i-type layer can be disposed on the first p-type layer. The first n-type layer can be disposed on the first i-type layer. In some embodiments, the first photovoltaic cell 530 can correspond to the first photovoltaic cell 134 described above. For example, the first p-type layer can correspond to the p-type thin film silicon layer 114; the first i-type layer can correspond to the i-type thin film silicon layer 116; and the first n-type layer can correspond to the n-type thin film silicon layer 118. In some embodiments, the first i-type layer is not present in the first photovoltaic cell 530 (e.g., a P-N junction). An optional conductive substrate layer 540 can be disposed on the first photovoltaic cell 134 (i.e., on the first n-type layer). The optional conductive substrate layer 540 can correspond to the conductive layer 120, as discussed above. In some embodiments, the optional conductive substrate layer 540 at least partially reflects a portion of light 518 (e.g., wavelengths less than about 750 nm) that was not initially absorbed by the first photovoltaic cell 530, thereby increasing the efficiency of the device 500.

A second photovoltaic cell 550 is in electrical communication with the first photovoltaic cell 530. For example, the second photovoltaic cell 550 can be in physical contact with the first photovoltaic cell 530. Alternatively, the second photovoltaic cell 550 can be in electrical communication, e.g., through the optional conductive substrate layer 540, with the first photovoltaic cell 530. In some embodiments, the second photovoltaic cell 550 can include amorphous silicon, amorphous SiGe, microcrystalline Si, microcrystalline SiGe, or combinations thereof. The second photovoltaic cell 550 can have a thickness of about 0.5 μm, about 1 about 2 μm, about 3 μm, about 4 μm, about 5 μm, about 6 μm, about 7 μm, about 8 μm, about 9 μm, about 10 μm, or ranges therebetween, including about 1 μm to about 3 μm. The second photovoltaic cell 550 can include a second p-type layer, a second i-type layer, and a second n-type layer (e.g., a P-i-N junction). The second p-type layer can be disposed on the first photovoltaic cell 530 or the optional conductive substrate layer 540. The second i-type layer can be disposed on the second p-type layer. The second n-type layer can be disposed on the second i-type layer. In some embodiments, the second photovoltaic cell can correspond to the second photovoltaic cell 136 described above. For example, the second p-type layer can correspond to the p-type thin Film silicon layer 122; the second i-type layer can correspond to the i-type thin film silicon layer 124; and the second n-type layer can correspond to the n-type thin film silicon layer 126. In some embodiments, the second i-type layer is not present in the second photovoltaic cell 550 (e.g., a P-N junction). In some embodiments, the device can include three or more photovoltaic cells.

The doped layer 560 is disposed on the second photovoltaic cell 550. For example, the doped layer 560 can be disposed on a proximal layer of the second photovoltaic cell 550 (e.g., the second n-type layer). The doped layer 560 can include microcrystalline silicon, microcrystalline SiG3, CdTe, CI(G)S, or other similar materials. The doped layer 560 can have a thickness of about 10 nm to about 1,000 nm, about 50 nm to about 500 nm, or about 100 nm, about 200 nm, about 300 nm, about 400 nm, about 500 nm, about 600 nm, about 700 nm, about 800 nm, about 900 nm, about 1,000 nm, or ranges therebetween. The doped layer 560 and the proximal layer of the second photovoltaic cell 550 are doped with materials of the same polarity. For example, the proximal layer and the doped layer 560 can both include a n-type dopant (i.e., negative polarity). Alternatively, both layers can include a p-type dopant. The proximal layer and the doped layer 560 can include the same or different dopant materials.

A first concentration of a first dopant in the doped layer 560 is greater than a second concentration of a second dopant in the proximal layer (e.g., the second n-type layer) of the second photovoltaic cell 550. The first concentration can be at least about 2 times, about 5 times, about 10 times, about 20 times, about 30 times, about 40 times, or about 50 times greater than the second concentration. In some embodiments, the first concentration can be between about 1×10¹⁸/cm³ to about 1×10²⁰/cm³, about 5×10¹⁸/cm³ to about 5×10¹⁹/cm³, or about 1×10¹⁹/cm³. The relatively high first concentration of the doped layer 560 can repel minority carriers from the textured layer 570. For example, the relatively high first concentration of the doped layer 560 can be adapted to create an electric field or back surface field (e.g., due to a band offset) that can repel minority carriers (e.g., electrons) in the second photovoltaic cell 550. By repelling minority carriers, the efficiency of the photovoltaic device 500 can be improved by minimizing recombination of majority (e.g., holes) and minority (e.g., electrons) carriers that can occur due to defects in the textured layer 570, which can be laser processed in some embodiments. For example, textured layer 570 can include a Lamberrian texture that can include voids, dangling bonds, and/or crystal defects that can inhibit the mobility of carriers (e.g., minority carriers), which can lead to recombination. By minimizing recombination, an anneal of the textured layer 570 can be avoided or minimized, e.g., by reducing the thermal budget (i.e., combination of anneal time and temperature). A minimal thermal budget can prevent the crystallization of the first photovoltaic cell 530, which can include amorphous silicon.

The conductive substrate layer 580 is disposed on the textured silicon layer 570. In some embodiments, the textured layer 570 can correspond to the laser processed silicon layer 126, as discussed above. In some embodiments, the conductive substrate layer 580 can correspond to the conductive layer 128. The optional reflector layer 590 can be disposed on the conductive substrate layer 580. The optional reflector layer 590 may be of any suitable material such as zinc oxide or a transparent conductive oxide layer. The optional reflector layer 590 can be between about 5 nm to about 5,000 nm thick, about 1 nm to about 1,000 nm, about 1,000 nm to about 2,000 nm, about 2,000 nm to about 3,000 nm, about 3,000 nm to about 4,000 nm, about 4,000 nm to about 5,000 nm, about 500 nm to about 1,000 nm, about 100 nm to about 500 nm, 5 nm to 500 nm, or ranges therebetween. The optional reflector layer 590 can reflect a portion of light (e.g., wavelengths greater than about 750 nm) that was not initially absorbed by the second photovoltaic cell 550, thereby increasing the efficiency of the device 500. The substrate layer 600 is disposed on the optional reflector layer 590 or the conductive substrate layer 580. The substrate layer 600 can correspond to the encapsulant layer 130.

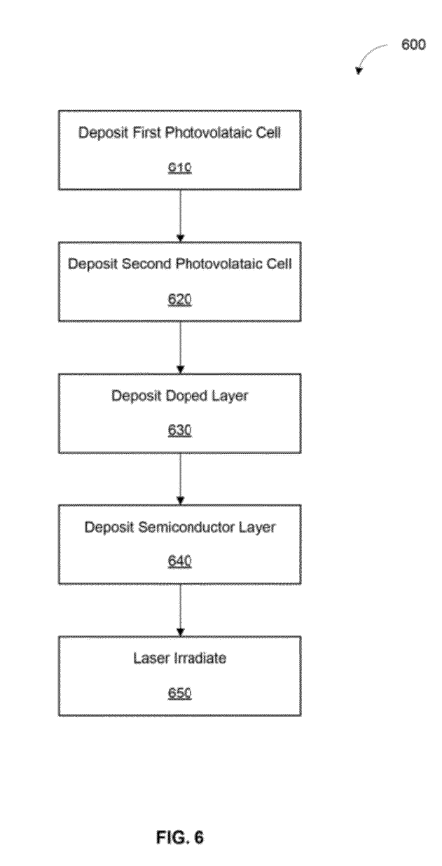

In some embodiments, a method of manufacturing a photovoltaic device (e.g., the photovoltaic device 500) is disclosed, as illustrated in FIG. 6. The method includes depositing a first photovoltaic cell (e.g., the first photovoltaic cell 530) on a substrate (step 610), depositing a second photo voltaic cell (e.g., the second photovoltaic cell 550) on the first photovoltaic cell (step 620), depositing a doped layer (e.g., the doped layer 560) on the second photovoltaic cell (step 630), depositing a semiconductor layer on the doped layer (step 640), and irradiating at least a portion of the semiconductor layer with a laser (step 650) e.g., to form the textured layer 570. In some embodiments, step 610 can correspond to steps 310, 312, 314, and 316 described above. Optionally, the method can include step 318 (depositing a conductive interlayer), described above, after step 610. Step 620 can correspond to steps 320, 322, and 324 described above. In step 630, a doped layer (e.g., the doped layer 580) is deposited on the second photovoltaic cell (formed in step 620). In step 640, a semiconductor layer (e.g., a microcrystalline semiconductor layer) is deposited on the n-type layer (deposited in step 324). Step 650 can correspond to step 324. The method can include one or more additional steps as described in relation to FIG. 3, including laser annealing (e.g., step 324), depositing a conducting substrate layer, e.g., substrate layer 580 (e.g., step 328), and depositing a substrate layer, e.g., the substrate layer 600 (e.g., step 330). In some embodiments, an optional reflector layer (e.g., the optional reflector layer 590) is deposited between the conducting substrate layer and the substrate layer (e.g., steps 328 and 330).

The present invention should not be considered limited to the particular embodiments described above, but rather should be understood to cover all aspects of the invention as fairly set out in the attached claims. Various modifications, equivalent processes, as well as numerous structures to which the present invention may be applicable, will be readily apparent to those skilled in the art to which the present invention is directed upon review of the present disclosure. The claims are intended to cover such modifications.

1. A photovoltaic device comprising
a first photovoltaic cell;
a second photovoltaic cell in electrical communication with the first photovoltaic cell;
a semiconductor layer having a textured portion; and
a doped layer configured to create a back surface field, the doped layer disposed between a proximal layer of the second photovoltaic cell and the semiconductor layer.

2. The device of claim 1, wherein the doped layer comprises a first dopant having a first polarity and the proximal layer of the second photovoltaic cell comprises a second dopant having a second polarity.

3. The device of claim 2, wherein the first polarity is the same as the second polarity.

4. The device of claim 3, wherein the first polarity and the second polarity are negative.

5. The device of claim 2, wherein the proximal layer of the second photovoltaic cell comprises the semiconductor layer.

6. The device of claim 2, wherein a first concentration of the first dopant is at least about two times a second concentration of the second dopant.

7. The device of claim 6, wherein the first concentration of the first dopant is at least about five times the second concentration of the second dopant.

8. The device of claim 7, wherein the first concentration of the first dopant is at least fifty times the second concentration of the second dopant.

9. The device of claim 3, wherein the first dopant comprises a same dopant material as the second dopant.

10. The device of claim 2, wherein a concentration of the first dopant is between about 1×10¹⁸/cm³ to about 1×10²⁰/cm³.

11. The device of claim 10, wherein the concentration of the first dopant is about 5×10¹⁸/cm³.

12. The device of claim 1, wherein the doped layer is configured to repel a minority carrier.

13. The device of claim 12, wherein the minority carrier comprises electrons.

14. The device of claim 1, further comprising an electromagnetic radiation reflecting layer disposed between the semiconductor layer and a substrate.

15. The device of claim 1, further comprising an electromagnetic radiation reflecting layer disposed between the first and second photovoltaic cells.

16. The device of claim 1, wherein the first and second photovoltaic cells are comprised of silicon.

17. The device of claim 16, wherein the first photovoltaic cell is comprised of amorphous silicon.

18. The device of claim 16, wherein the second photovoltaic cell is comprised of microcrystalline

19. The device of claim 1, wherein the first photovoltaic cell is disposed on a substrate and the second photovoltaic cell is disposed on the first photovoltaic cell.

20. The device of claim 19, wherein the substrate is flexible.

21. The device of claim 19, further comprising a conductive layer disposed between the first photovoltaic cell and the substrate.

22. The device of claim 19, further comprising a conductive layer disposed between the semiconductor layer and a substrate.

23. The device of claim 1, wherein the first photovoltaic cell comprises a P-N junction.

24. The device of claim 1, wherein the first photovoltaic cell comprises a P-i-N junction.

25. The device of claim 1, wherein the second photovoltaic cell comprises a P-N junction.

26. The device of claim 1, wherein the second photovoltaic cell comprises a P-i-N junction.

27. The device of claim 1, wherein the textured portion is formed by a laser-treatment process.

28. The device of claim 1, wherein the textured portion of the semiconductor layer creates a Lambertian distribution of light.

29. A photovoltaic device comprising
a substrate layer;
a conductive substrate layer disposed on the substrate layer;
a first p-type layer disposed on the conductive substrate layer;
a first i-type layer disposed on the first p-type layer;
a first n-type layer disposed on the first i-type layer;
a first conductive layer disposed on the first n-type layer;
a second p-type layer disposed on the first conductive layer;
a second i-type layer disposed on the second p-type layer;
a second n-type layer disposed on the second i-type layer;
a doped layer disposed on the second n-type layer, the doped layer configured to create a back surface field;
a semiconductor layer disposed on the doped layer, wherein the semiconductor layer comprises a textured portion; and
a second conductive layer disposed on the semiconductor layer.

30. The photovoltaic device of claim 29, further comprising an electromagnetic radiation reflecting layer disposed on the second conductive layer.

31. The photovoltaic device of claim 29, wherein the textured portion is formed by a laser-treatment process.

32. The photovoltaic device of claim 29, wherein the doped layer comprises a first dopant material having a first polarity and the semiconductor layer comprises a second dopant material having a second polarity, wherein the first and second dopant polarities are the same.

33. The photovoltaic device of claim 29, wherein the first and second dopant polarities are negative.

34. A method of manufacturing, comprising:
depositing a first photovoltaic cell on a substrate;
depositing a second photovoltaic cell on the first photovoltaic cell;
depositing a doped layer configured to create back surface field on the second photovoltaic cell, the back surface field layer having a dopant concentration greater than a dopant concentration of a proximal layer of the second photovoltaic cell;
depositing a semiconductor layer on the doped layer; and
forming a textured portion of the semiconductor layer.

35. The method of claim 34, further comprising depositing an electromagnetic radiation reflecting layer on the semiconductor layer.

36. The method of claim 34, wherein the textured portion is formed by irradiating at least a portion of the semiconductor layer with a pulsed laser source.
